(19) United States
(12) Patent Application Publication
(10) Pub. No.: US 2010/0020588 A1
(43) Pub. Date: Jan. 28, 2010

(54) SEMICONDUCTOR MEMORY DEVICE

(75) Inventor: Susumu SHUTO, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/509,326

(22) Filed: Jul. 24, 2009

(30) Foreign Application Priority Data
Jul. 25, 2008 (JP) 2008-191652

(51) Int. Cl. G11C 11/22; G11C 11/24; G11C 8/00

(52) U.S. Cl. 365/145; 365/149; 365/230.03

(57) ABSTRACT

A semiconductor memory device includes cell blocks configured to have a plurality of memory cells connected in series, each memory cell comprising a ferroelectric capacitor and a cell transistor connected in parallel with each other; word lines connected to gates of a plurality of the cell transistors; block selectors connected to first ends of the cell blocks; bit lines connected to the first ends of the cell blocks via the block selectors; and plate lines connected to second ends of the cell blocks, wherein the first ends of first and second cell blocks of the cell blocks respectively sharing the word lines are connected to the same bit line via the block selectors different from each other, and the second ends of the first and the second cell blocks respectively are connected to the plate lines different from each other.

### CROSS-REFERENCE TO RELATED APPLICATION

This application is based upon and claims the benefit of priority from the prior Japanese Patent Applications No. 2008-191652, filed on Jul. 25, 2008, the entire contents of which are incorporated herein by reference.

### BACKGROUND OF THE INVENTION

1. Field of the Invention

The present invention relates to a semiconductor memory device, and for example relates to a ferroelectric memory.

2. Related Art

In a conventional ferroelectric memory, cell transistors within plural cell blocks connected to the same bit line are connected to different word lines, respectively.

When a memory cell is downscaled to provide a small memory chip or increase a memory capacitance, an interval between plural adjacent bit lines becomes small. A bit line capacitance includes a capacitance of unselected memory cells present between a selected memory cell and a bit line, and a coupling capacitance of the bit line and adjacent bit lines, in addition to a capacitance of the bit line itself. Therefore, when an interval between adjacent bit lines becomes small, a bit line capacitance becomes large following an increase of the coupling capacitance between the adjacent bit lines.

In reading the ferroelectric memory, a sense amplifier detects a bit line potential (a signal amount of a bit line) when an electric charge accumulated in a ferroelectric capacitor of the memory cell is transferred to the bit line. Therefore, when a ratio C_{BL}/C_{AC} of a bit line capacitance C_{BL} to an accumulation charge capacitance C_{AC} of the ferroelectric capacitor becomes large, a signal amount of the bit line decreases. That is, when the bit line capacitance C_{BL} becomes large, a difference between a signal amount of data “1” and a signal amount of data “0” becomes small, and this has a risk that the sense amplifier erroneously detects data.

By downscaling, the thickness of a bit line is normally decreased and the length of the bit line is also decreased. Therefore, downscaling of a memory is also considered to decrease a bit line capacitance. However, actually, an increase of a coupling capacitance between adjacent bit lines becomes larger than a reduction of a capacitance of the bit line itself. Consequently, the downscaling of the memory increases the bit line capacitance. As a result, there is a problem that a difference between a signal mount of the data “1” and a signal amount of the data “0” becomes small by the downscaling of the memory (along progress of generation).

### SUMMARY OF THE INVENTION

A semiconductor memory device according to an embodiment of the present invention comprises: a plurality of cell blocks configured to have a plurality of memory cells connected in series, each memory cell comprising a ferroelectric capacitor and a cell transistor connected in parallel with each other; a plurality of word lines connected to gates of a plurality of the cell transistors; a plurality of block selectors connected to first ends of the cell blocks; a plurality of bit lines connected to the first ends of the cell blocks via the block selectors; and a plurality of plate lines connected to second ends of the cell blocks, wherein the first ends of first and second cell blocks of the cell blocks respectively sharing the word lines are connected to the same bit line via the block selectors different from each other, and the second ends of the first and the second cell blocks respectively are connected to the plate lines different from each other.

### BRIEF DESCRIPTION OF THE DRAWINGS

FIG. 1 shows a configuration of a ferroelectric memory according to a first embodiment of the present invention;

FIG. 2 shows an internal configuration of a broken-line frame 3 in FIG. 1;

FIG. 3 is a timing diagram showing a data read operation of the ferroelectric memory according to the first embodiment;

FIG. 4 is a timing diagram showing a data write operation or a data restore operation of the ferroelectric memory according to the first embodiment;

FIG. 5 shows a configuration of a ferroelectric memory according to a modification of the first embodiment;

FIG. 6 shows a configuration of a ferroelectric memory according to a second embodiment of the present invention;

FIG. 7 and FIG. 8 are timing diagrams showing a read operation and a write operation of a ferroelectric memory according to the second embodiment;

FIG. 9 shows a configuration of a ferroelectric memory according to a third embodiment of the present invention;

FIG. 10 and FIG. 11 are timing diagrams showing a read operation and a write operation of a ferroelectric memory according to the third embodiment;

FIG. 12 shows a configuration of a ferroelectric memory according to a fourth embodiment of the present invention;

FIG. 13 shows a configuration of a ferroelectric memory according to a fifth embodiment of the present invention;

FIG. 14 is a timing diagram showing a read operation of the ferroelectric memory according to the fifth embodiment; and

FIG. 15 is a timing diagram showing a write operation of the ferroelectric memory according to the fifth embodiment.

### DETAILED DESCRIPTION OF THE INVENTION

Embodiments of the present invention will be explained below in detail with reference to the accompanying drawings. Note that the invention is not limited thereto.

### First Embodiment

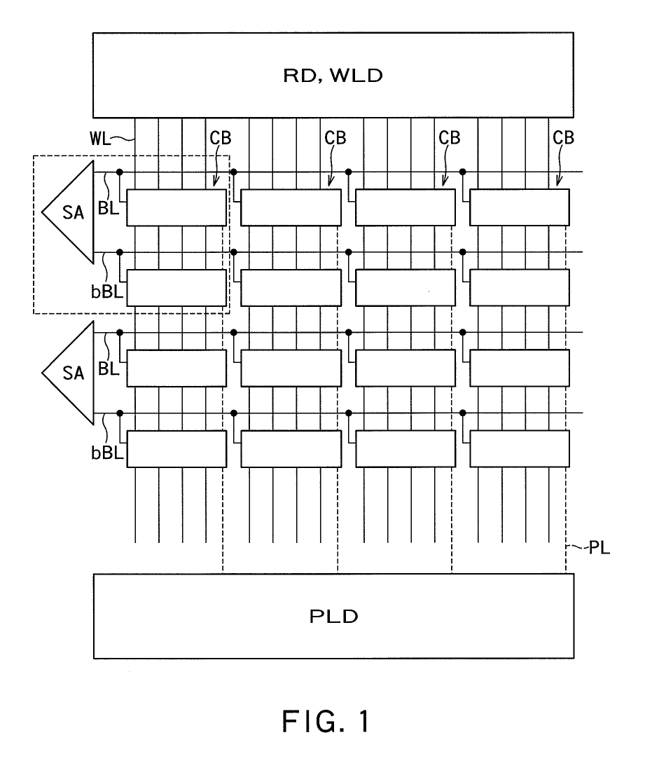

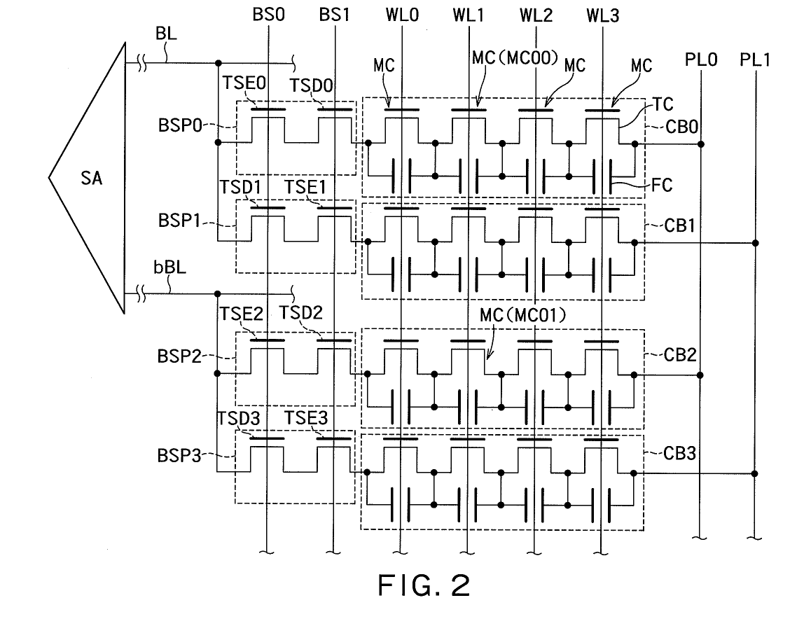

FIG. 1 shows a configuration of a ferroelectric memory according to a first embodiment of the present invention. FIG. 2 shows an internal configuration of a broken-line frame 3 in FIG. 1. The ferroelectric memory according to the first embodiment includes plural word lines WL extended to a row direction, plural bit lines BL extended to a column direction orthogonal with a row direction, and plural plate lines PL extended to a row direction. In FIG. 1, the plural plate lines PL are shown by one broken line to distinguish the plate lines from the word lines WL. In FIG. 1, a block selecting unit is omitted.

Cell blocks CB including plural memory cells MC are arranged two dimensionally in a matrix shape. One memory cell MC stores binary data or multi-bit data into a ferroelectric capacitor. The memory cells MC are formed on a semiconductor substrate. The memory cells MC are provided corresponding to intersections between the word lines WL and the bit lines BL and bBL. The word lines WL are provided corresponding to the memory cells MC arranged in a row direction. The bit lines BL and bBL are provided corresponding to the memory cells MC arranged in a column direction. The plate lines PL are provided corresponding to cell blocks arranged in a row direction.

A word-line driving circuit WLD is connected to the word lines WL. The word-line driving circuit WLD selects a part (singular or plural) of the word lines WL and inactivates the selected word line WL following an address received from a row decoder RD. Sense amplifiers SA are connected to bit line pairs BL and bBL. Each sense amplifier SA detects data from a memory cell propagated to the bit line pairs BL and bBL at a data reading time. Each sense amplifier SA applies a voltage to the bit line pairs BL and bBL at a data writing time. Accordingly, the sense amplifier SA can read or write data from or into the memory cells MC connected to the selected word lines.

FIG. 1 shows the cell blocks CB arranged in a matrix shape of 4×4. However, the number of the cell blocks CB is not limited to this.

As shown in FIG. 2, the ferroelectric memory according to the first embodiment is a TC parallel-unit series-connected ferroelectric memory. The TC parallel-unit series-connected (hereinafter, also “chain type”) ferroelectric memory is a ferroelectric memory having both ends of a ferroelectric capacitor FC connected between a source and a drain of a cell transistor TC to form a unit cell (a memory cell MC), and having plural unit cells (memory cells MC) connected in series.

The ferroelectric memory according to the first embodiment operates in a 2T2C mode. The 2T2C mode is a system that out of a pair of the bit lines BL and bBL connected to the sense amplifier SA, data from one bit line is set as a reference of data from the other bit line, and data from the other bit line is set as a reference of data from the one bit line, thereby detecting the data of the bit line pair BL and bBL. Therefore, complimentary data (the data “1” and the data “0”) are stored in two memory cells MC sharing word lines and connected to the bit line pair BL and bBL. The complementary data are handled as one bit data. That is, at a data detecting time, the two complementary data stored in the two memory cells MC sharing word lines and connected to the bit line pair BL and bBL are simultaneously detected as one bit data. The first embodiment has a folded bit line structure.

The ferroelectric memory includes plural cell blocks CBO to CB3, each being configured by having plural memory cells MC connected in series, each memory cell MC including the ferroelectric capacitor FC and the cell transistor TC connected in parallel with each other. The word lines WL0 to WL3 are connected to gates of the cell transistors TC of the memory cells MC.

One ends of the cell blocks CB0 to CB3 are connected to one ends of block selecting units BSP0 to BSP3, respectively. The other ends of the cell blocks CB0 and CB2 are connected to a plate line PL0, and the other ends of the cell blocks CB1 and CB3 are connected to a plate line PL1. The other ends of the block selecting units BSP0 and BSP1 are connected to the bit line BL, and the other ends of the block selecting units BSP2 and BSP3 are connected to the bit line bBL. That is, the bit line BL is connected to the cell blocks CB0 and CB1 via the block selecting units BSP0 and BSP1. The bit line bBL is connected to the cell blocks CB2 and CB3 via the block selecting units BSP2 and BSP3.

As explained above, in the first embodiment, the one ends of the cell blocks CB0 and CB1 sharing the word lines WL0 to WL3 are connected to the same bit line BL via the mutually different block selecting units BSP0 and BSP1. That is, the cell blocks CB0 and CB1 sharing the word lines WL0 to WL3 share the same bit line BL. The other ends of the cell blocks CB0 and CB1 are connected to the mutually different plate lines PL0 and PL1. Similarly, the cell blocks CB2 and CB3 sharing the word lines WL0 to WL3 share the same bit line bBL. The other ends of the cell blocks CB2 and CB3 are connected to mutually different plate lines PL2 and PL3.

The block selecting units BSP0 to BSP3 include enhancement-type FETs (field effect transistors) (hereinafter, “E-type transistors”) and depletion-type FETs (hereinafter, “D-type transistors”) connected in series between the cell blocks CB0 to CB3 and the bit lines BL or bBL. The E-type transistors are transistors becoming in a conductive state (on state) by driving a gate potential. The D-type transistors are transistors in a conductive state (on state) regardless of a gate potential.

The block selecting unit BSP0 has an E-type transistor TSE0 and a D-type transistor TSD0 connected in series between the bit line BL and the cell block CB0. The E-type transistor TSE0 is provided at a bit line BL side, and the D-type transistor TSD0 is provided at a cell block CB0 side. The block selecting unit BSP1 has an E-type transistor TSE1 and a D-type transistor TSDL connected in series between the bit line BL and the cell block CB1. The D-type transistor TSDL is provided at a bit line BL side, and the E-type transistor TSE1 is provided at a cell block CB1 side.

The block selecting unit BSP2 has an E-type transistor TSE2 and a D-type transistor TSD2 connected in series between the bit line bBL and the cell block CB2. The E-type transistor TSE2 is provided at a bit line bBL side, and the D-type transistor TSD2 is provided at a cell block CB2 side. The block selecting unit BSP3 has an E-type transistor TSE3 and a D-type transistor TSD3 connected in series between the bit line bBL and the cell block CB3. The D-type transistor TSD3 is provided at a bit line bBL side, and the E-type transistor TSE3 is provided at a cell block CB3 side.

Gates of the transistors TSE0, TSD1, TSE2, and TSE3 are connected to a block selection line BS0. The transistors TSE0, TSD1, TSE2, and TSE3 are controlled by a signal of the block selection line BS0. A positional relationship between the E-type transistor and the D-type transistor in the block selecting units BSP0 and BSP1 is opposite. Therefore, when the block selection line BS0 is activated, the E-type transistor TSE0 is turned on, and the E-type transistor TSE1 is in the off state. Consequently, the cell block CB0 is connected to the bit line BL via the block selecting unit BSP0, and the cell block CB1 is disconnected from the bit line BL. When the block selection line BS1 is activated, the cell block CB1 is connected to the bit line BL via the block selecting unit BSP1, and the cell block CB0 is disconnected from the bit line BL. In this way, the block selecting units BSP0 and BSP1 can selectively connect either the cell block CB0 or CB1 to the bit line BL.

A positional relationship between the E-type transistor and the D-type transistor in the block selecting units BSP2 and BSP3 is also opposite. Therefore, the block selecting units BSP2 and BSP3 can selectively connect either the cell block CB2 or CB3 to the bit line bBL.

Activation means to turn on or drive an element or a circuit, and inactivation means to turn off or suspend an element or a circuit. Therefore, a HIGH (high potential level) signal can be an activation signal, and a LOW (low potential level) signal can be an activation signal. For example, an NMOS transistor is activated by setting a gate to HIGH. On the other hand, a PMOS transistor is activated by setting a gate to LOW.

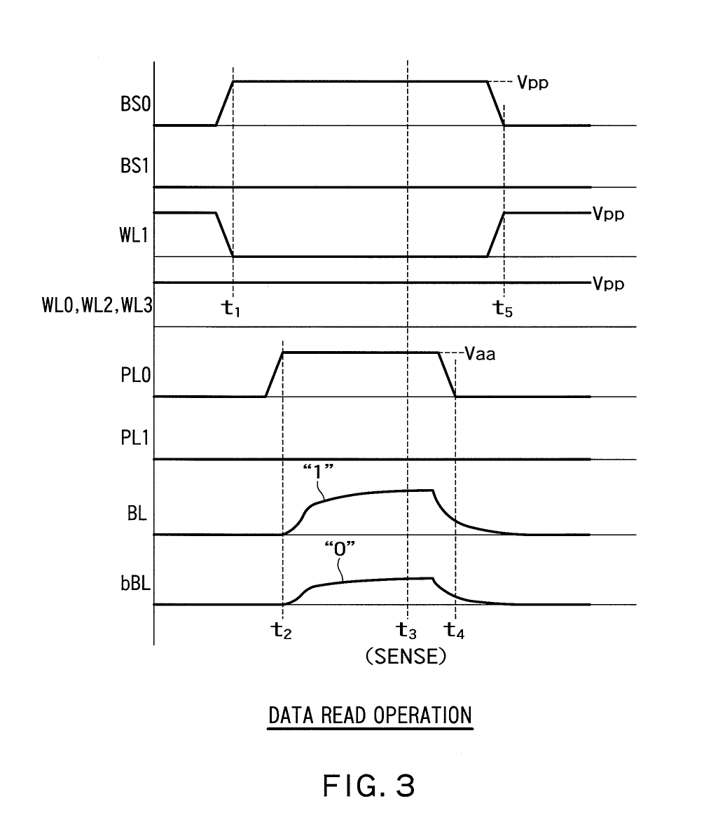

FIG. 3 is a timing diagram showing a data read operation of the ferroelectric memory according to the first embodiment. FIG. 3 shows a method of reading data stored in memory cells MC00 and MC01.

In this case, the block selection line BS0 is selected. When the block selection line BS0 is selected, the bit line BL is connected to the cell block CB0, and the bit line bBL is connected to the cell block CB2. Accordingly, the word line WL1 is inactivated, and the plate line PL0 is activated. Consequently, data of the memory cell MC00 is transmitted to the bit line BL, and data of the memory cell MC01 is transmitted to the bit line bBL. Because the memory in the first embodiment operates in the 2T2C mode, two data stored in the memory cells MC00 and MC01 are complementary data. Therefore, the sense amplifier SA connected to the bit line pair BL and bBL can detect data stored in the memory cells MC00 and MC01 via the bit line pair BL and bBL.

The operation in the first embodiment is explained in further detail. Before t1, the word lines WL0 to WL3 are activated at a high level potential (Vpp), and all cell transistors TC within the memory cell MC are in the on state. Accordingly, potentials of both electrodes of all ferroelectric capacitors FC become substantially equal, and an electric field is little applied to all ferroelectric capacitors FC.

At t1, the block selection line BS0 is activated at the high level potential. Accordingly, the cell blocks CB0 and CB2 are connected to the bit line BL. At the same time, the selected word line WL1 is inactivated. Other unselected word lines WL0, WL2, and WL3 maintain an active state. Consequently, only the cell transistors TC of the selected memory cells MC00 and MC11 become in the off state, and all cell transistors TC of other unselected memory cells maintain the on state. As a result, a potential difference between the bit line BL and the plate line PL0 is applied to only the ferroelectric capacitor FC of the selected memory cell MC00 within the cell block CB0, and is not applied to other ferroelectric capacitors FC within the cell block CB0.

Similarly, a potential difference between the bit line bBL and the plate line PL0 is applied to only the ferroelectric capacitor FC of the selected memory cell MC01 within the cell block CB2, and is not applied to other ferroelectric capacitors FC within the cell block CB2. The cell blocks CB1 and CB3 are disconnected from the bit lines BL and bBL by the E-type transistors TSE1 and TSE3.

At t2, a potential of the plate line PL0 is raised to a high level potential (Vaa). Accordingly, signals corresponding to data stored in the selected memory cells MC00 and MC01 are transmitted to the bit lines BL and bBL, respectively. In the first embodiment, the data “1” as the logic high is transmitted to the bit line BL, and the data “0” as the logic low is transmitted to the bit line bBL. Vpp is a voltage of a level at which the voltage of Vaa can be sufficiently transferred to the sense amplifier SA via the block selecting unit and the cell transistor. Vaa is a voltage of writing data to memory cells.

At t3, the sense amplifier SA is activated. The sense amplifier SA detects a potential difference (a signal difference) between the bit lines BL and bBL, and latches this signal difference.

Thereafter, at t4, the plate line BL0 is inactivated at a low level potential. At t5, the block selection line BS0 is inactivated at the low level potential, and the word line WL1 is activated at the high level potential.

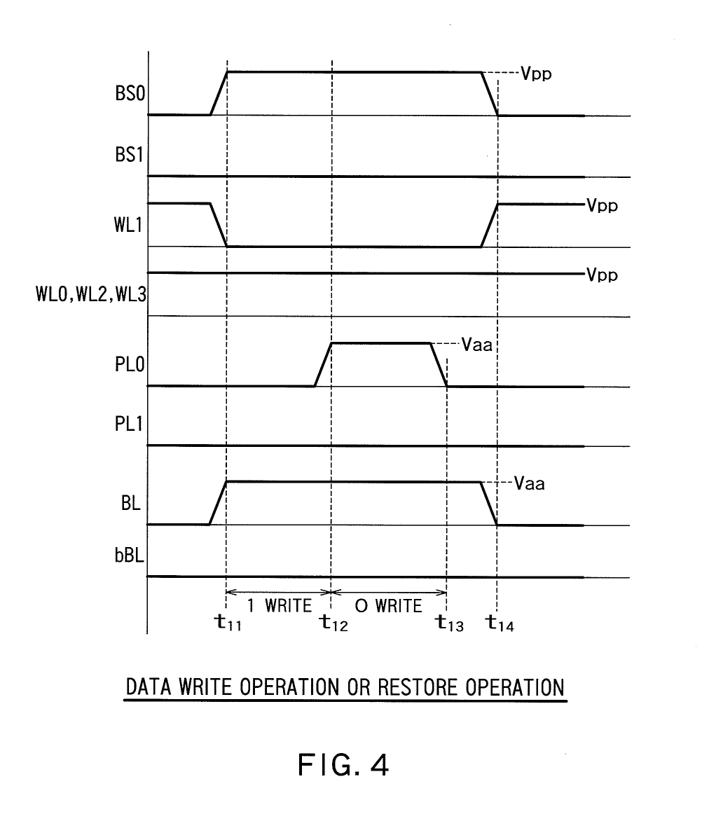

The ferroelectric memory is a destructive read-out type memory. The destructive read-out type memory is a memory in which data stored in a memory cell is degraded (destroyed) when the data is read out from the memory cell. Therefore, when data is read out from the memory cell of the destructive read-out type memory, external write data needs to be written into the memory cell, or data latched by the sense amplifier SA needs to be restored into an original memory cell, as shown in FIG. 4.

FIG. 4 is a timing diagram showing a data write operation or a data restore operation of the ferroelectric memory according to the first embodiment. FIG. 4 shows a method of writing (restoring) data into the memory cells MC00 and MC01.

Before t11, the word lines WL0 to WL3 are activated at the high level potential, and all cell transistors TC within the memory cell MC are in the on state. Accordingly, potentials of both electrodes of all ferroelectric capacitors FC are substantially equal, and an electric field is little applied to all ferroelectric capacitors FC.

At t11, the block selection line BS0 is activated at the high level potential. Accordingly, the cell blocks CB0 and CB2 are connected to the bit line BL. At the same time, the selected word line WL1 is inactivated. Other unselected word lines WL0, WL2, and WL3 maintain the active state. Consequently, only the cell transistors TC of the selected memory cells MC00 and MC11 become in the off state, and all cell transistors TC of other unselected memory cells maintain the on state. As a result, a potential difference between the bit line BL and the plate line PL0 is applied to only the ferroelectric capacitor FC of the selected memory cell MC00 within the cell block CB0, and is not applied to other ferroelectric capacitors FC within the cell block CB0.

Similarly, a potential difference between the bit line bBL and the plate line PL0 is applied to only the ferroelectric capacitor FC of the selected memory cell MC01 within the cell block CB2, and is not applied to other ferroelectric capacitors FC within the cell block CB2.

During t11 to t12, a potential corresponding to the write data (restore data) is given to the bit line pair BL and bBL. In this case, a potential of the bit line BL is raised to the high level potential, and the bit line bBL is maintained at the low level potential. That is, the data “1” is transmitted to the bit line BL, and the data “0” is transmitted to the bit line bBL.

In this case, a potential of the plate line PL0 is the low level potential. Therefore, a potential difference does not occur between the bit line bBL and the plate line PL0, but a predetermined potential difference occurs between the bit line BL and the plate line PL0. The potential difference between the bit line BL and the plate line PL0 is applied to the ferroelectric capacitor FC of the selected memory cell MC00. On the other hand, the potential difference is not applied to the ferroelectric capacitor FC of the selected memory cell MC01. Accordingly, the data “1” is written into only the ferroelectric capacitor FC of the selected memory cell MC00.

At t12, a potential of the plate line PL0 is raised to the high level potential. In this case, the potential of the bit line BL remains as the high level potential, and potential of the bit line bBL remains as the low level potential. Therefore, there is no potential difference between the bit line BL and the plate line PL0, but a predetermined potential difference occurs between the bit line bBL and the plate line PL0. The potential difference between the bit line bBL and the plate line PL0 is applied to the ferroelectric capacitor FC of the selected memory cell MC01. On the other hand, the potential difference is not applied to the ferroelectric capacitor FC of the selected memory cell MC00. Accordingly, the data “0” is written into only the ferroelectric capacitor FC of the selected memory cell MC01. In this case, a direction of the electric field applied to the ferroelectric capacitor is opposite to a direction of the electric field at the time of writing the data “1” (t11 to t12). Accordingly, the data “1” is written into the selected memory cell MC00, and the data “0” is written into the selected memory cell MC01.

Thereafter, at t13, the plate line PL0 is inactivated at the low level potential. At t14, the block selection line BS0 is inactivated at the low level potential, the word line WL1 is activated at the high level potential, and the bit line BL is lowered to the low level potential. After t4, the memory becomes in a standby state (a precharged state).

FIG. 2 and FIG. 4 show the operation of the ferroelectric memory when the block selection line BS0 is selected. An operation of the ferroelectric memory when the block selection line BS1 is selected can be easily understood from the operation of selecting the block selection line BS0, and therefore explanations thereof will be omitted.

As explained above, in the first embodiment, the plural cell blocks CB0 and CB1 (CB2 and CB3) sharing the word lines WL0 to WL3 are connected to the same bit line BL (bBL). Therefore, an interval between the adjacent bit lines BL and bBL becomes larger than a conventional interval. Consequently, in the first embodiment, a coupling capacitance between adjacent bit lines can be decreased from a conventional coupling capacitance, and the bit line capacitance can be decreased. A reduction of the bit line capacitance leads to a suppression of a reduction of a signal difference between the data “1” and the data “0”. When the interval between the bit lines becomes large, a design layout of the sense amplifier SA becomes easy.

Instead of decreasing the bit line capacitance, a width of the wiring of the bit line can be increased and bit line resistance can be decreased. In this case, while a reduction effect of the bit line capacitance cannot be expected so much, an RC delay of the bit line can be decreased.

However, usually, an RC delay of the word line is larger than that of the bit line, and is ruling. In this case, because it is not necessary to consider the RC delay of the bit line, it is preferable to sufficiently decrease a bit line capacitance without increasing a width of the bit line.

Conventionally, even when a total size of a memory chip is tried to be decreased by downscaling the memory cells, increase of a coupling capacitance between adjacent bit lines interferes the downscaling of the memory chip.

According to the first embodiment, plural cell blocks are arranged in parallel between adjacent bit lines. Therefore, even when memory cells are sufficiently downscaled, an interval between the adjacent bit lines can be maintained to be larger than a conventional interval. Consequently, even when a memory chip size is decreased as far as possible, increase of a bit line capacitance does not become a significant problem.

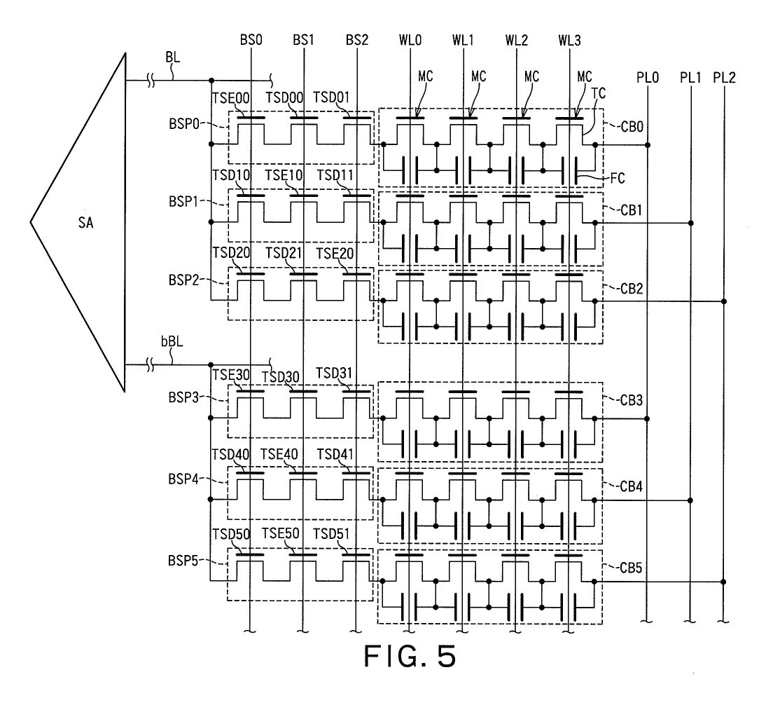

When downscaling of memory cells is further progressed and when the increase of a coupling capacitance of adjacent bit lines becomes a problem, the number of cell blocks arranged in parallel between the adjacent bit lines can be increased to three or more. For example, as shown in FIG. 5, the number of cell blocks connected to the bit line BL (BL0) can be increased to three by sharing the word lines WL0 to WL3. With this arrangement, an interval between the bit lines BL and bBL is further increased. Therefore, a size of the memory chip can be further decreased corresponding to the downscaling of the memory cells.

The number of the block selecting units BSP0 to BSP2 (BSP3 to BSP5) and the number of the block selection lines BS0 to BS2 need to be set equal to the number of the cell blocks CB0 to CB2 (CB3 to CB5) arranged in parallel between the adjacent bit lines. This is because one cell block needs to be selectively connected to the bit line BL (bBL), out of the cell blocks CB0 to CB2 (CB3 to CB5) arranged in parallel between the adjacent bit lines. Therefore, the number of the block selecting units and the number of the block selection lines need to be increased by the same number, corresponding to the increase of the number of cell blocks arranged in parallel between the adjacent bit lines.

Further, the number of D-type transistors included in one block selecting unit also needs to be increased, corresponding to the increase of the number of cell blocks arranged in parallel between the adjacent bit lines. For example, in FIG. 5, each of the block selecting units BSP0 to BSP5 has one E-type transistor and two D-type transistors.

E-type transistors TSE00 to TSE20 of the block selecting units BSP0 to BSP2 corresponding to the cell blocks CB0 to CB2 arranged in parallel between the adjacent bit lines are connected to the block selection lines BS0 to BS2 different from each other. This is because one cell block out of the block selecting units BSP0 to BSP2 needs to be selectively connected to the bit line BL. For a similar reason, E-type transistors TSE30 to TSE50 of the block selecting units BSP3 to BSP5 are connected to the block selection lines BS0 to BS2 different from each other.

Further, the number of plate lines also needs to be increased corresponding to an increase of the number of cell blocks arranged in parallel between adjacent bit lines. For example, in FIG. 5, the block selecting units BSP0 to BSP2 are connected respectively to the plate lines PL0 to PL2 different from each other. The block selecting units BSP3 to BSP5 are connected respectively to the plate lines PL0 to PL2 different from each other.

In FIG. 2, the number of the memory cells MC included in one cell block is four. However, the number of the memory cells MC included in one cell block can be equal to or larger than five. When the number of the memory cells MC included in one cell block is large, a proportion of an installation area of the block selecting units becomes small. This means that a drawback of the increase of a chip size can be suppressed based on the arrangement of the block selecting units.

In the first embodiment, a metal wiring can be used instead of the D-type transistor. For example, the bit line BL and the E-type transistor TSE1 can be short-circuited by the metal wiring, instead of using the D-type transistor TSD1. Other D-type transistors can be similarly replaced by the metal wiring.

### Second Embodiment

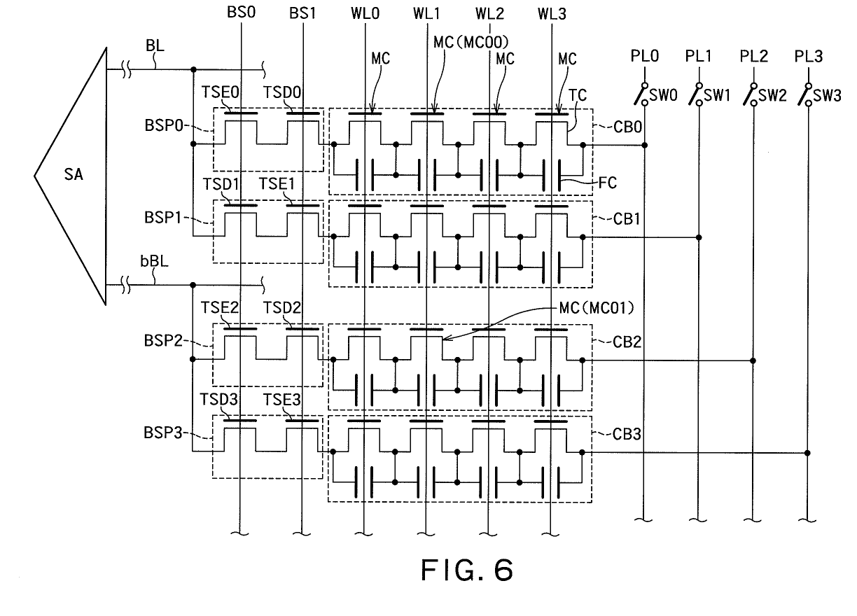

FIG. 6 shows a configuration of a ferroelectric memory according to a second embodiment of the present invention. A total configuration in the second embodiment can be similar to the configuration shown in FIG. 1. The second embodiment is different from the first embodiment in that the number of plate lines is different from that in the first embodiment and that switches SW0 to SW3 are provided in each plate line in the second embodiment. Other configurations of the second embodiment can be similar to those in the first embodiment.

While the second embodiment has a folded bit line structure like that in the first embodiment, an operation is performed in a b 1T1C mode. The 1T1C mode is a system that at the time of detecting data from one of the bit line pair BL and bBL connected to the sense amplifier SA, reference data at an intermediate potential between “0” and “1” is transmitted to the other bit line. The reference data is generated by using a dummy cell, or is externally generated. Therefore, at a data detection time, a sense amplifier detects data of only one memory cell MC connected to the bit line BL or bBL. That is, data within one memory cell MC is handled as one bit data.

The cell blocks CB0 to CB3 are connected to the mutually different plate lines PL0 to PL3. The switches SW0 to SW3 are present in the plate lines PL0 to PL3. The switches SW0 to SW3 are configured to be able to disconnect the plate lines PL0 to PL3 from the cell blocks CB0 to CB3 or connect the plate lines PL0 to PL3 to the cell blocks CB0 to CB3.

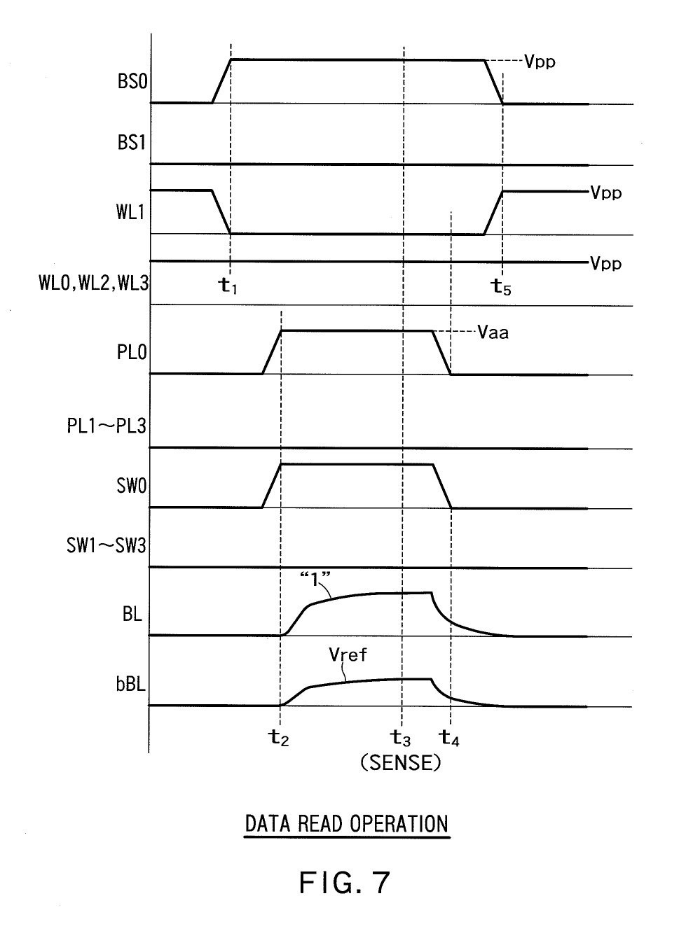

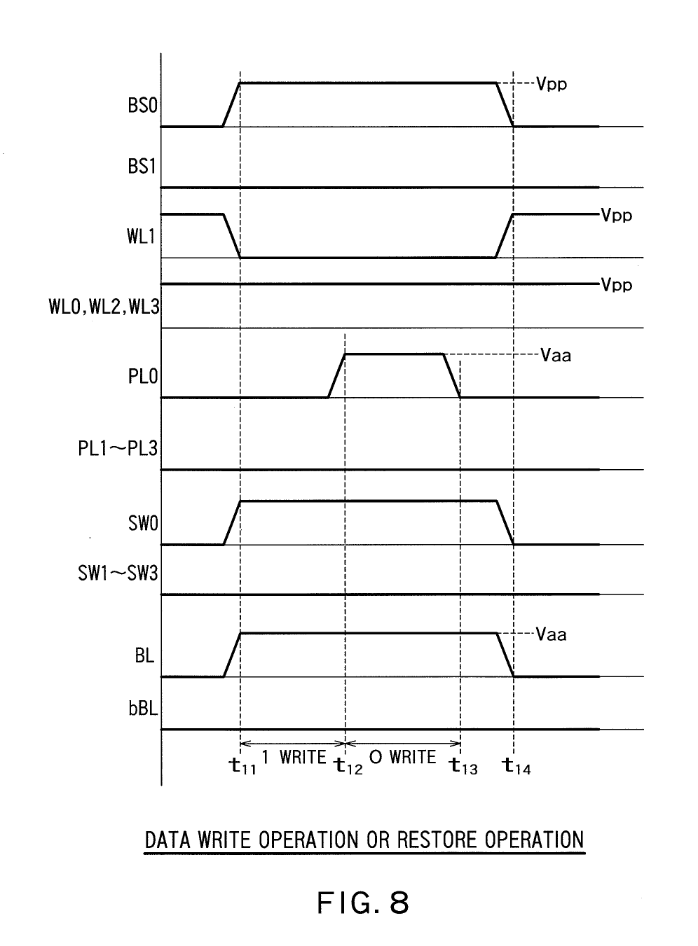

FIG. 7 and FIG. 8 are timing diagrams showing a read operation and a write operation of a ferroelectric memory according to the second embodiment. In the read and write operations in the second embodiment, only a switch provided in the plate line connected to a selected memory cell becomes in the on state, and other switches remain in the off state. The operation of other signals is similar to that shown in FIG. 3 and FIG. 4.

When the memory cell MC00 is selected, for example, only the switch SW0 provided in the plate line PL0 becomes in the on state, and other switches SW1 to SW3 remain in the off state. The plate line PL0 is driven in this state. Accordingly, the sense amplifier SA can detect data from the selected memory cell MC00 or can write data into the selected memory cell MC00.

When the block selection line BS0 is selected, not only the cell block CB0 is connected to the bit line BL, but also the cell block CB2 is also connected to the bit line bBL. However, because the switch SW2 is in the off state at this time, the plate line PL2 is in the floating state. Therefore, even when reference data is transmitted to the bit line bBL, an electric field is little applied to the memory cell MC01. As a result, only the data of the selected memory cell MC00 can be detected without disturbing the data of the memory cells within the unselected cell blocks CB1 to CB3.

Similarly, at the time of selecting the memory cell MC included in the cell block CBi (i=0 to 3), the switch SWi is set to the on state, and other switches are left in the off state. Accordingly, the sense amplifier SA can detect data of the memory cell MC within the cell block CBi. As explained above, according to the second embodiment, the ferroelectric memory can be operated in the 1T1C mode by adding the plate lines PL2 and PL3 and the switches SW0 to SW3. Further, the second embodiment can obtain effects of the first embodiment.

### Third Embodiment

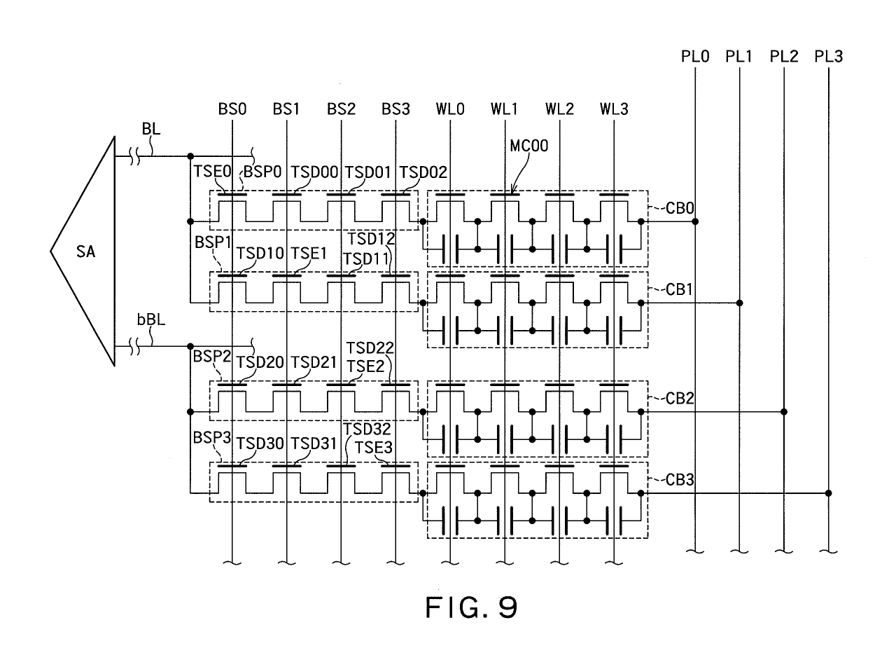

FIG. 9 shows a configuration of a ferroelectric memory according to a third embodiment of the present invention. A total configuration in the third embodiment can be similar to that shown in FIG. 1. The third embodiment is different from the first embodiment in the number of plate lines and an internal configuration of the block selecting units BSP0 to BSP3. Other configurations in the third embodiment can be similar to those in the first embodiment. While the third embodiment has a folded bit line structure like that in the first embodiment, the operation is performed in the 1T1C mode similarly to the second embodiment.

The cell blocks CB0 to CB3 are connected to the mutually different plate lines PL0 to PL3. The block selecting units BSP0 to BSP3 have one E-type transistor and three D-type transistors connected in series, respectively. The E-type transistors TSE0 to TSE3 within the block selecting units BSP0 to BSP3 are connected respectively to the block selection lines BS0 to BS3 different from each other. Accordingly, one cell block out of the cell blocks CB0 to CB3 is connected to either the bit line BL or bBL. When the block selection line BS0 is selected, the cell block CB0 corresponding to this block selection line is connected to the bit line BL.

Accordingly, the sense amplifier SA can detect data of the selected memory cell MC included in one cell block out of the cell blocks CB0 to CB3, or can write data into this selected memory cell MC.

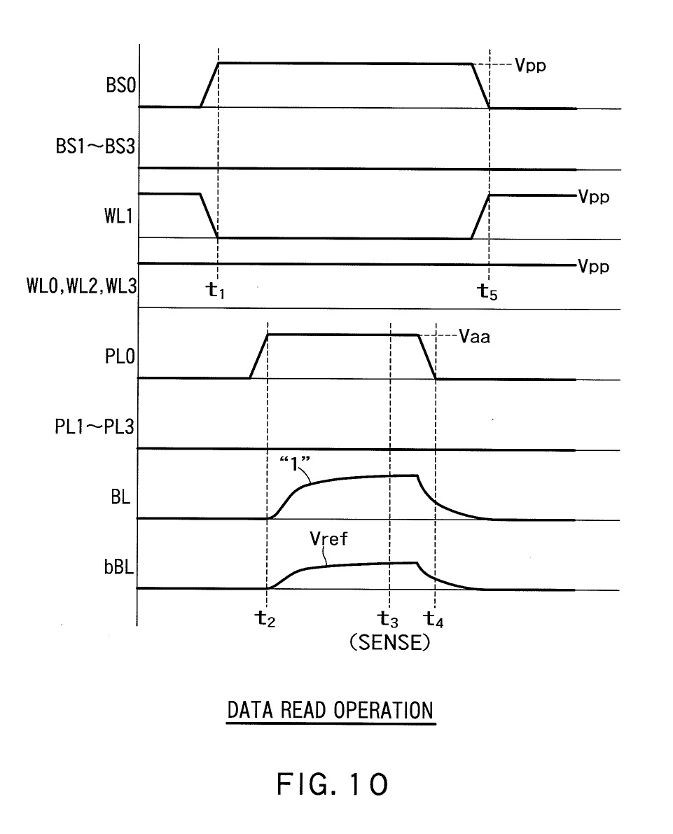

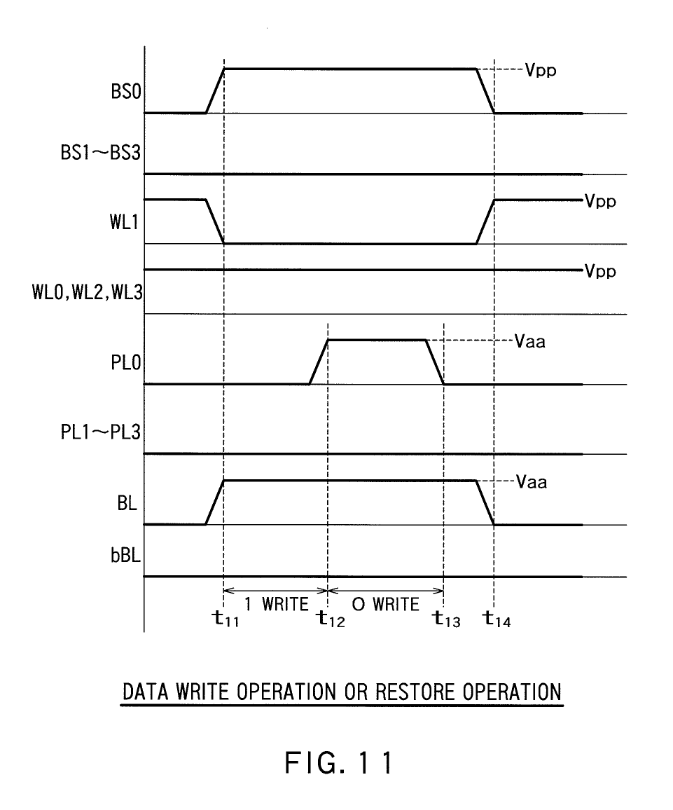

FIG. 10 and FIG. 11 are timing diagrams showing a read operation and a write operation of a ferroelectric memory according to the third embodiment. In the read and write operations in the third embodiment, all block selection lines except one selected block selection line are in the inactive state. That is, out of the E-type transistors TSE0 to TSE3, one E-type transistor is in the on state, and other E-type transistors are in the off state. Operations of other signals are similar to the operation shown in FIG. 3 and FIG. 4.

At the time of selecting the memory cell MC00, only the block selection line BS0 is activated, and the block selection lines BS1 to BS3 remain in the inactive state. In this case, only the E-type transistor TSE0 becomes on. Accordingly, only the cell block CB0 is connected to the bit line BL, and other cell blocks CB1 to CB3 are disconnected from the bit lines BL and bBL. The plate line PL0 is driven in this state. Consequently, the sense amplifier SA can detect data of the selected memory cell MC00, or can write data into the selected memory cell MC00.

Although reference data is transmitted to the bit line bBL, the bit line bBL is disconnected from the cell blocks CB2 and CB3. Therefore, disturbance to the memory cells MC within the cell blocks CB2 and CB3 does not occur.

Similarly, at the time of selecting the memory cell MC included in the cell block CBi (i=0 to 3), the block selection line BSi is activated, and other block selection lines are kept in the inactive state. Accordingly, the sense amplifier SA can detect data of the memory cell MC within the cell block CBi.

As explained above, according to the third embodiment, the ferroelectric memory can be operated in the 1T1C mode by adding the plate lines PL2 and PL3 and also by changing the configuration of the block selecting units BSP0 to BSP3. Further, the third embodiment can obtain effects of the first embodiment.

### Fourth Embodiment

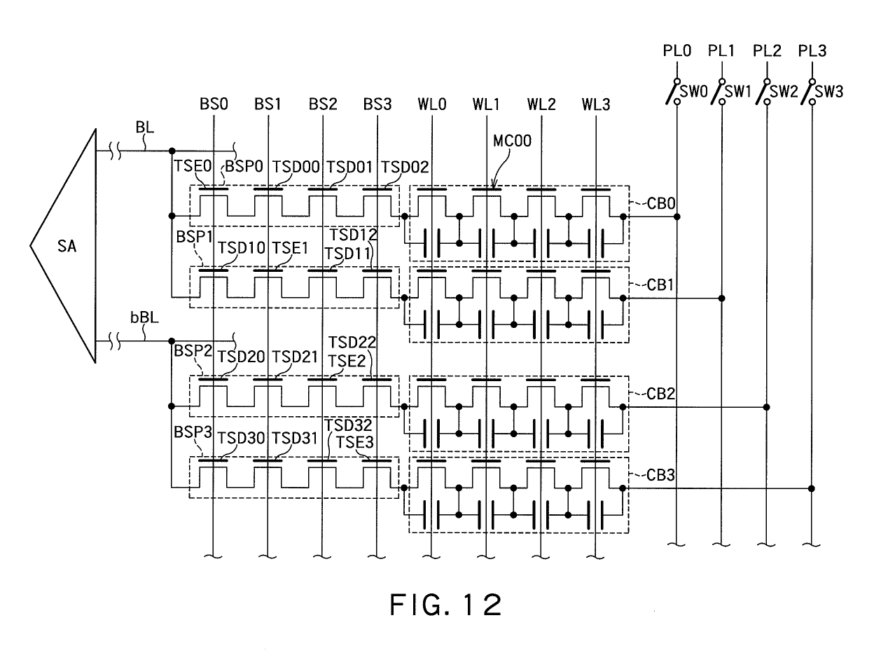

FIG. 12 shows a configuration of a ferroelectric memory according to a fourth embodiment of the present invention. The fourth embodiment is a combination of the second and third embodiments. That is, the fourth embodiment is different from the first embodiment in that the number of plate lines is different from that of the first embodiment, that an internal configuration of the block selecting units BSP0 to BSP3 is different from that of the first embodiment, and that the switches SW0 to SW3 are provided. Based on the above, an operation is performed in the 1T1C mode in the fourth embodiment.

Read and write operations in the fourth embodiment can be easily surmised from the description of the operation in the second and third embodiments, and therefore explanations thereof will be omitted. According to the fourth embodiment, out of the memory cells MC connected to a selected word line, both electrodes of the unselected memory cells MC are disconnected from the bit line and the plate line. Therefore, in the fourth embodiment, disturbance to the data of the memory cells MC becomes smaller than that in the second and third embodiments.

However, because a circuit scale of the block selecting units BSP0 to BSP3 becomes large and because the switches SW0 to SW3 are provided, a size of a memory chip becomes larger than that in the second and third embodiments. Further, the fourth embodiment can obtain effects of the first embodiment.

### Fifth Embodiment

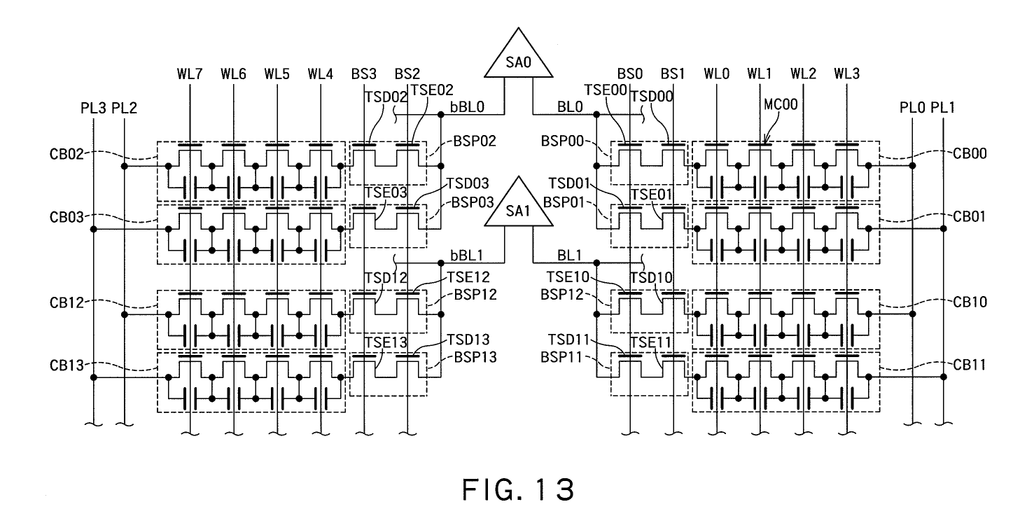

FIG. 13 shows a configuration of a ferroelectric memory according to a fifth embodiment of the present invention. The fifth embodiment is different from the first embodiment in that the ferroelectric memory according to the fifth embodiment has an open bit line structure.

In the fifth embodiment, an operation is performed in the 1T1C mode. A configuration corresponding to a sense amplifier SA0 is explained below. A configuration corresponding to a sense amplifier SA1 is similar to that corresponding to the sense amplifier SA0, and therefore explanations thereof will be omitted.

The sense amplifier SA0 is connected to a bit line pair BL0 and bBL0 extended to both sides of the sense amplifier SA0. Plural cell blocks CB00 and CB01 connected to the same bit line BL0 share the word lines WL0 to WL3, and are connected to the mutually different plate lines PL0 and PL1. Plural cell blocks CB02 and CB03 connected to the same bit line bBL0 share the word lines WL4 to WL7, and are connected to the mutually different plate lines PL2 and PL3, respectively.

The cell blocks CB00 and CB01 connected to the same bit line BL0 and the cell blocks CB02 and CB03 connected to the same bit line bBL0 do not share the word lines. That is, the cell blocks CB00 and CB01 and the cell blocks CB02 and CB03 are provided corresponding to a word line set WL0 to WL3 and a word line set WL4 to WL7 that are mutually different from each other. The cell blocks CB00 and CB01 and the cell blocks CB02 and CB03 do not share the plate lines either. That is, the cell blocks CB00, CB01, CB02, and CB03 are connected to the plate lines PL0 to PL3 different from each other.

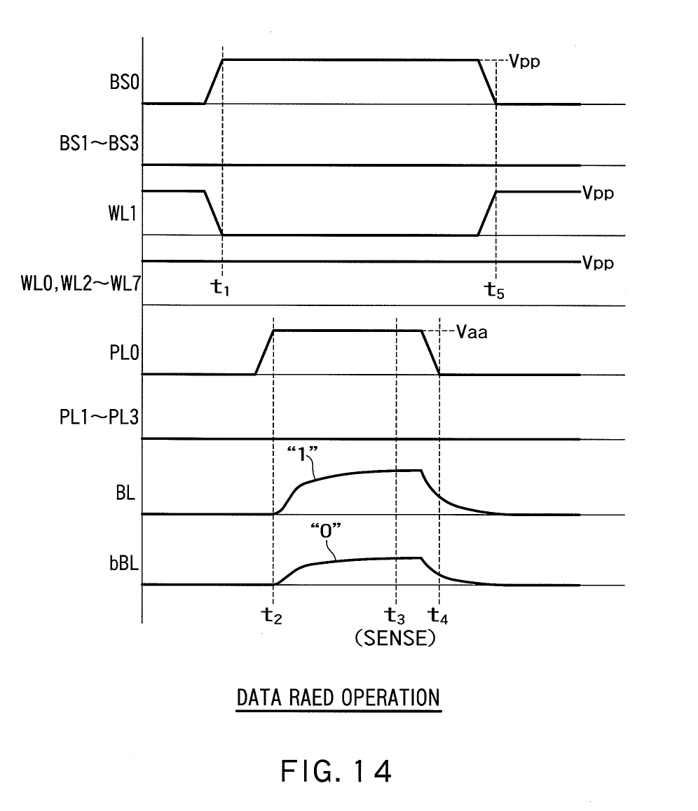

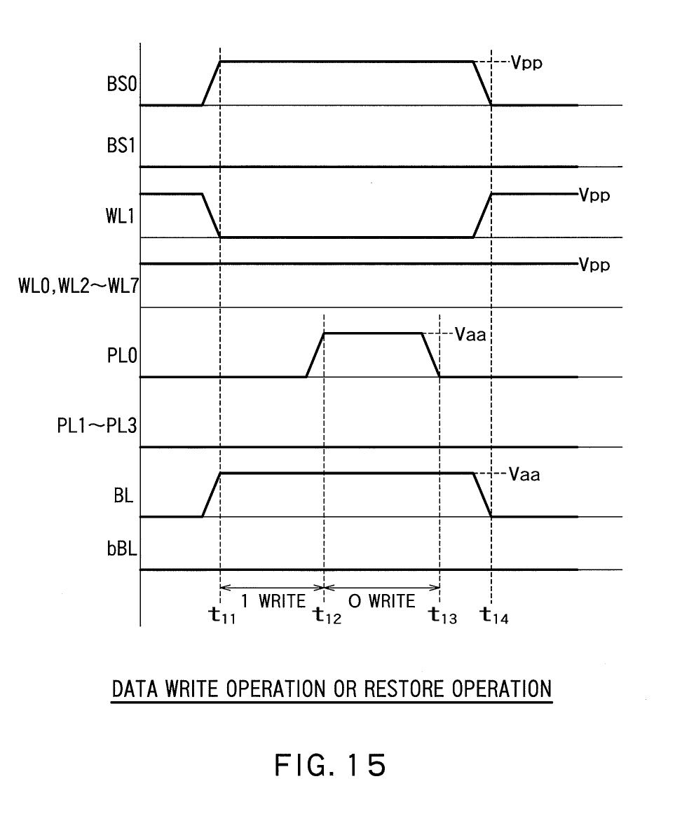

FIG. 14 and FIG. 15 are timing diagrams showing a read operation and a write operation of the ferroelectric memory according to the fifth embodiment, respectively. In the read and write operations in the fifth embodiment, a plate line and a block selecting unit connected to a cell block including a selected memory are driven.

For example, at the time of selecting the memory cell MC00, only the block selection line BS0 is activated, and the block selection lines BS1 to BS3 are left in the inactive state. With this arrangement, only the cell block CB00 is connected to the bit line BL0, and other cell blocks CB01 to CB03 are disconnected from the bit lines BL0 and bBL0.

The plate line PL0 is driven in this state. Accordingly, the sense amplifier SA0 can detect data of the selected memory cell MC00 or can write data into the selected memory cell MC00.

At the same time, in the sense amplifier SA1, only the cell block CB10 is connected to the bit line BL1. Other cell blocks CB11 to CB13 are disconnected from the bit lines BL1 and bBL1.

Because the plate line PL0 is driven in this state, the sense amplifier SA1 can detect data of the selected memory cell MC10 or can write data into the selected memory cell MC10.

In this case, reference data is transmitted to the bit lines bBL0 and bBL1, but the bit lines bBL0 and bBL1 are disconnected from the cell blocks CB02 and CB03 and the cell blocks CB12 and CB13, respectively. Therefore, disturbance to the memory cells MC in the cell blocks CB02 and CB03 and the cell blocks CB12 and CB13 does not occur.

Similarly, at the time of selecting the memory cell MC included in the cell blocks CB01 and CB11, the block selection line BS1 is activated, and the plate line PL1 is activated. At the time of selecting the memory cell MC included in the cell blocks CB02 and CB12, the block selection line BS2 is activated and the plate line PL2 is activated. At the time of selecting the memory cell MC included in the cell blocks CB03 and CB13, the block selection line BS3 is activated and the plate line PL3 is activated.

As explained above, according to the fifth embodiment, in the ferroelectric memory having the open bit line structure, plural cell blocks can be arranged in parallel between adjacent bit lines. Accordingly, the fifth embodiment can obtain the same effects as the first embodiment.

In the second to fifth embodiments, as explained with reference to FIG. 5, the number of cell blocks arranged in parallel between the adjacent bit lines can be increased. In this case, numbers of the block selecting units and the block selection lines need to be increased corresponding to the number of cell blocks arranged in parallel. Similarly to the first embodiment, the number of the memory cell MC included in one cell block can be five or more. Further, instead of the D-type transistor, a metal wiring (metal bridge) can be used.

1. A semiconductor memory device comprising:
a plurality of cell blocks comprising a plurality of memory cells connected in series, each memory cell comprising a ferroelectric capacitor and a cell transistor connected in parallel with each other;
a plurality of word lines connected to gates of a plurality of the cell transistors;
a plurality of block selectors connected to first ends of the cell blocks;
a plurality of bit lines connected to the first ends of the cell blocks via the block selectors; and
a plurality of plate lines connected to second ends of the cell blocks, wherein
the first ends of first and second cell blocks of the cell blocks sharing the word lines are connected to the same bit line via the block selectors respectively, and
the second ends of the first and the second cell blocks are connected to the plate lines respectively.

2. The device of claim 1, wherein each block selector comprises one enhancement-type FET and at least one depletion-type FET connected in series between the cell blocks and the bit lines.

3. The device of claim 1, wherein a number of the cell blocks sharing the word lines and connected to the same bit line is equal to a number of the enhancement-type FET and the depletion-type FET in each of the block selectors connected to the cell blocks.

4. The device of claim 1, further comprising a plurality of switches in the plate lines, wherein a first switch connected to the plate line corresponding to a memory cell selected in either a data read operation or a data write operation is set to a conductive state and the switches other than the first switch are set to a nonconductive state.

5. The device of claim 2, further comprising a plurality of switches in the plate lines, wherein a first switch connected to the plate line corresponding to a memory cell selected in either a data read operation or a data write operation is set to a conductive state and the switches other than the first switch are set to a nonconductive state.

6. The device of claim 3, further comprising a plurality of switches in the plate lines, wherein a first switch connected to the plate line corresponding to a memory cell selected in either a data read operation or a data write operation is set to a conductive state and the switches other than the first switch are set to a nonconductive state.

7. The device of claim 1, wherein the cell blocks connected to respective bit lines are connected to the word lines respectively, and are also connected to the plate lines respectively.

8. The device of claim 1, wherein each block selector comprises one enhancement-type FET and at least one metal wiring connected in series between the cell blocks and the bit lines.

9. The device of claim 1, wherein a number of the cell blocks sharing the word lines and connected to the same bit line is equal to a number of block selection lines connected to one of the block selectors connected to the cell blocks.
